(19) United States
(12) Patent Application Publication
(10) Pub. No.: US 2009/0243010 A1
(43) Pub. Date: Oct. 1, 2009

(54) THINFILM DEPOSITION METHOD, THINFILM DEPOSITION APPARATUS, AND THINFILM SEMICONDUCTOR DEVICE

(75) Inventors: Kazuyasu Nishikawa, Tokyo (JP); Satoshi Yamakawa, Tokyo (JP); Shinichi Izuo, Tokyo (JP); Hiroshi Fukumoto, Tokyo (JP)

Correspondence Address: OBLON, SPIVAK, MCCLELLAND MAIER & NEUSTADT, P.C., 1940 DUKE STREET, ALEXANDRIA, VA, 22314, US

(73) Assignee: MITSUBISHI ELECTRIC CORPORATION, Chiyoda-ku (JP)

(21) Appl. No.: 12/412,914

(22) Filed: Mar. 27, 2009

(30) Foreign Application Priority Data
Mar. 28, 2008 (JP) 2008-088711
Feb. 27, 2009 (JP) 2009-046917

(51) Int. Cl. H01L 31/0248; H01L 31/18; C23C 16/50

(52) U.S. Cl. 257/431; 438/57; 118/723 R; 257/E31.002

(57) ABSTRACT

A substrate holding unit, a plasma treatment chamber, and a nanoparticle supplying chamber are housed in a single chamber. The substrate holding unit holds a substrate. The plasma treatment chamber includes a gas passage for introducing a source gas to a vicinity of the substrate and a plasma generating unit that generates a plasma from the source gas. The nanoparticle supplying chamber includes a spraying member for spraying a nanoparticle-containing medium onto a surface of the substrate.

### BACKGROUND OF THE INVENTION

1. Field of the Invention

The present invention relates to a technology for fabricating a thinfilm semiconductor device, such as a thinfilm silicon-based solar cell and a thinfilm transistor, formed with thinfilm semiconductor layers.

2. Description of the Related Art

A thinfilm solar cell, which is one of the photoelectric conversion devices, is classified into a thinfilm silicon-based solar cell (for example, amorphous silicon-based and nanocrystalline silicon-based) and a polycrystalline silicon-based solar cell according to the type of a photogenerating layer. The thinfilm silicon-based solar cell is formed by sequentially depositing a first electrode, a photoelectric conversion layer, and a second electrode on a main surface of an optically-transparent substrate such as a glass substrate and a resin sheet. The first electrode is made of transparent conductive material such as tin dioxide (SnO₂), zinc oxide (ZnO), or tin-doped indium oxide (hereinafter, “indium tin oxide (ITO)”). The photoelectric conversion layer is made of a thinfilm silicon layer. The second electrode is made of aluminum, silver, or ZnO.

So far, various measures have been taken to increase the efficiency of the thinfilm silicon-based solar cell. One of the measures employs a photoelectric conversion layer, which is a thinfilm silicon layer, with a structure in which photoelectric conversion layers most suitable for the wavelength band of the sunlight are combined to increase the efficiency. For example, the structure includes a first photoelectric conversion layer formed with the amorphous silicon and a second photoelectric conversion layer formed with the nanocrystalline silicon, in which the first photoelectric conversion layer is to perform a photoelectric conversion in a wavelength range from the low wavelength to the mid wavelength of the sunlight and the second photoelectric conversion layer is to perform a photoelectric conversion in a wavelength range from the mid wavelength to the long wavelength of the sunlight. In this manner, by using a photoelectric conversion layer having a high quantum efficiency in each wavelength range, the broad wavelength band of the sunlight can be effectively utilized so that the efficiency of the thinfilm silicon-based solar cell can be increased.

Another approach to increase the efficiency of the photogenerating layer is to form an amorphous silicon semiconductor layer including silicon nanoparticles. For example, proposed methods include a method of forming an amorphous silicon semiconductor layer including nanoparticles by the plasma enhanced chemical vapor deposition (PECVD) method with a source gas and a gas including the nanoparticles introduced in a reaction chamber (see, for example, Japanese Patent No. 3162781) and a method of forming an aggregate layer including nanoparticles by depositing silicon nanoparticles by the spray method (see, for example, Japanese Patent Application Laid-open No. 2000-101109).

However, in a thinfilm deposition apparatus described in Japanese Patent No. 3162781, which employs the PECVD method, it is not possible to achieve a uniform arrangement of the nanoparticles on a substrate because the nanoparticles are introduced with a carrier gas. Furthermore, because the nanoparticles are exposed to the plasma while floating in the vacuum and the electrons are faster than the ions, the nanoparticles are easily charged with a negative charge. For example, in the case of a parallel-plate plasma apparatus, because the nanoparticles are easily captured near an electrode to which the radio frequency is applied, if the plasma is extinguished, the nanoparticles floating around the electrode fall onto the surface of the substrate at once, resulting in a situation that the surface of a thinfilm is covered with the nanoparticles after forming the thinfilm. In addition, because the nanoparticles are introduced with the carrier gas into the reaction chamber through a gas pipe, the gas pipe is easily blocked. Moreover, it has a difficulty in changing the average particle size of the nanoparticles included in the thinfilm in the thickness direction of the thinfilm.

Similarly, a thinfilm deposition apparatus described in Japanese Patent Application Laid-open No. 2000-101109, which uses the spray method, has a difficulty in controlling locations and sizes of the nanoparticles that are generated by a recrystallization. Furthermore, a heating by a thermal spray causes an alteration of a base coating or a substrate.

### SUMMARY OF THE INVENTION

It is an object of the present invention to at least partially solve the problems in the conventional technology.

According to an aspect of the present invention, there is provided a thinfilm deposition method including plasma treatment processing including either one of depositing a thinfilm on a surface of a substrate by dissociating a source gas with a plasma and treating the surface of the substrate with the source gas; and nanoparticle arranging including arranging nanoparticles on the surface of the substrate that has been subjected to the plasma treatment processing by spraying a nanoparticle-containing fluid onto the surface of the substrate, wherein a treatment process in which the plasma treatment processing and the nanoparticle arranging are performed in a same chamber is defined as one cycle, and the thinfilm deposition method further comprises repeating the one cycle of the treatment process.

According to another aspect of the present invention, there is provided a thinfilm deposition apparatus including a substrate holding unit that holds a substrate while heating a part or whole of the substrate; a plasma treatment chamber that is connected to a source-gas supplying unit that supplies a source gas, the plasma treatment chamber including a gas passage for introducing the source gas to a vicinity of the substrate and a plasma generating unit that generates a plasma from the source gas supplied from the gas supplying pipe; a nanoparticle supplying chamber that is connected to a nanoparticle-containing-medium supplying unit that supplies a nanoparticle-containing medium that contains nanoparticles, the nanoparticle supplying chamber including a spraying member for spraying the nanoparticle-containing medium supplied from the nanoparticle-containing-medium supplying unit onto a surface of the substrate; a collecting unit that collects the source gas from the plasma treatment chamber and the nanoparticle-containing medium from the nanoparticle supplying chamber; and a chamber that commonly accommodates the substrate holding unit, the plasma treatment chamber, and the nanoparticle supplying chamber.

According to still another aspect of the present invention, there is provided a thinfilm semiconductor device including a transparent substrate; a first electrode formed on the substrate, the first electrode being made of transparent conductive material; a first semiconductor film formed on the first electrode, the first semiconductor film being made of first conductive semiconductor; a second semiconductor film formed on the first semiconductor film, the second semiconductor film being made of intrinsic semiconductor; a third semiconductor film formed on the second semiconductor film, the third semiconductor film being made of second conductive semiconductor; and a second electrode formed on the third semiconductor film. The second semiconductor film includes a plurality of uniformly-arranged nanoparticles having a predetermined average particle size.

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1 is a schematic diagram of a thinfilm deposition apparatus according to a first embodiment of the present invention;

FIG. 2 is a cross section of a nanoparticle supplying chamber and a plasma treatment chamber of the thinfilm deposition apparatus shown in FIG. 1, which is cut along a line A-A;

FIG. 3 is a schematic diagram for illustrating a relation between the nanoparticle supplying chamber, the plasma treatment chamber, and a substrate;

FIG. 4 is a schematic diagram of a plasma source in the plasma treatment chamber viewed from an electrode side;

FIG. 5 is a schematic diagram for illustrating a positional relation between the nanoparticle supplying chamber and the plasma treatment chamber, the substrate, and a heater viewed from above;

FIG. 6 is a cross section of a thinfilm silicon-based solar cell;

FIG. 7 is a schematic diagram for explaining a process flow of a thinfilm deposition process;

FIG. 8 is a schematic diagram for explaining an overall procedure of the thinfilm deposition process;

FIG. 9 is a schematic diagram of a thinfilm deposition apparatus according to a second embodiment of the present invention;

FIG. 10 is a schematic diagram of a thinfilm deposition apparatus according to a third embodiment of the present invention;

FIG. 11 is a schematic diagram for illustrating a positional relation between a nanoparticle supplying chamber and a plasma treatment chamber, a substrate, and a heater in the thinfilm deposition apparatus according to the third embodiment viewed from above;

FIG. 12 is a cross section of a thinfilm silicon-based solar cell fabricated by using the thinfilm deposition apparatus according to the second embodiment;

FIG. 13 is a schematic diagram of a thinfilm deposition apparatus according to a fourth embodiment of the present invention;

FIG. 14 is a schematic diagram of a thinfilm deposition apparatus according to a fifth embodiment of the present invention;

FIG. 15 is a schematic diagram of a thinfilm deposition apparatus according to a sixth embodiment of the present invention;

FIG. 16 is a schematic diagram of a thinfilm deposition apparatus according to a seventh embodiment of the present invention; and

FIG. 17 is a schematic diagram of a thinfilm deposition apparatus according to an eighth embodiment of the present invention.

### DETAILED DESCRIPTION OF THE PREFERRED EMBODIMENTS

Exemplary embodiments of the present invention are explained in detail below with reference to the accompanying drawings. The embodiments explained below shall not be construed to limit the present invention. Drawings of solar cells used in explanations of the embodiments are all schematic and not to scale, and therefore, a relation between thickness and width of a layer, ratios of layer thicknesses, and the like are different from the real measurements.

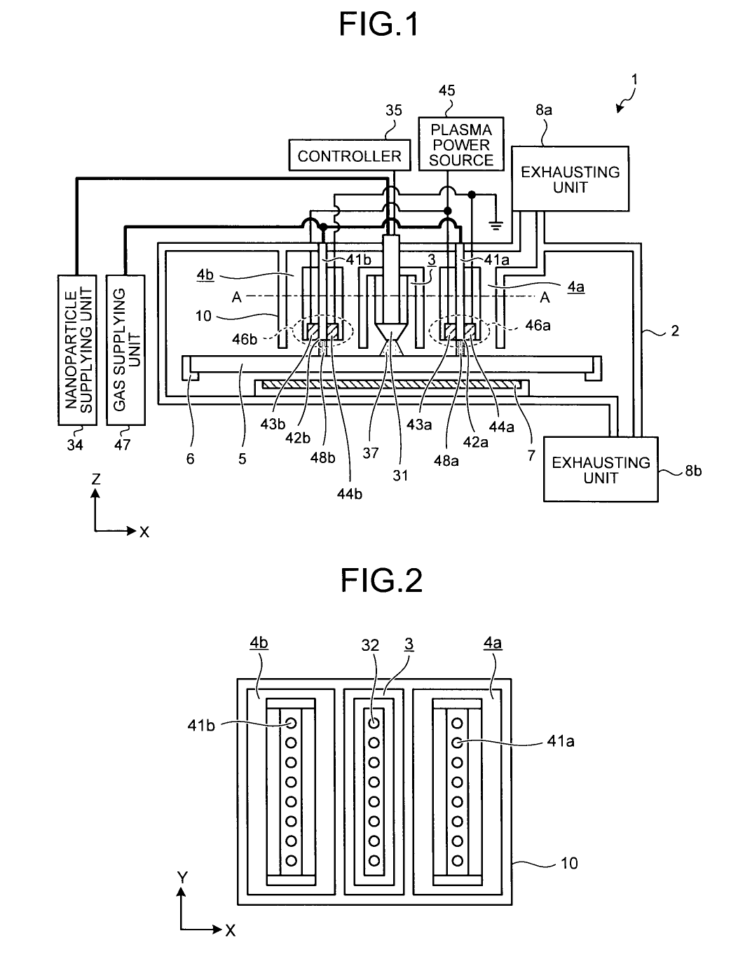

FIG. 1 is a schematic diagram of a thinfilm deposition apparatus 1 according to a first embodiment of the present invention. The thinfilm deposition apparatus 1 includes a main chamber 2, a nanoparticle supplying chamber 3 from which nanoparticles are sprayed, plasma treatment chambers 4a and 4b (hereinafter, also referred to as “plasma treatment chamber 4” as appropriate) each for generating a plasma to deposit a thinfilm, a substrate 5, and a substrate holder 6. The nanoparticle supplying chamber 3 includes a nozzle 31 that sprays a fluid that contains the nanoparticles (hereinafter, “a nanoparticle-containing fluid”). The nozzle 31 is arranged on the bottom side of the main chamber 2, and the upper part of the nanoparticle supplying chamber 3 is fixed at the top of the main chamber 2. The plasma treatment chambers 4a and 4b include plasma sources 46a and 46b each for generating a plasma, respectively. The plasma sources 46a and 46b are arranged on the bottom side of the main chamber 2, and the upper parts of the plasma treatment chambers 4a and 4b are fixed at the top of the main chamber 2. The substrate holder 6 is provided near the bottom of the main chamber 2 and it can be moved on the X-Y plane by a moving unit (not shown). A heater 7 is provided to heat the substrate 5 at a position below the substrate holder 6 facing the nanoparticle supplying chamber 3 and the plasma treatment chambers 4a and 4b across the substrate 5. Exhausting units 8a and 8b are provided on the main chamber 2 to exhaust a gas inside the main chamber 2.

FIG. 2 is a cross section of the nanoparticle supplying chamber 3 and the plasma treatment chambers 4a and 4b, which is cut along a line A-A shown in FIG. 1. In the first embodiment, the nanoparticle-containing fluid is sprayed from the nozzle 31 to arrange the nanoparticles on the substrate 5. Therefore, the nanoparticle supplying chamber 3 includes a container for the nanoparticle-containing fluid, and a nanoparticle supplying unit 34 is connected to the nanoparticle supplying chamber 3 through a nanoparticle supplying pipe 32. As shown in FIG. 2, the cross-sectional shape of the nanoparticle supplying chamber 3 on the X-Y plane is rectangular elongated in the Y-axis direction as in the case of the nanoparticle supplying chamber 3. The nanoparticle supplying chamber 3 includes a plurality of nanoparticle supplying pipes 32 arranged at virtually regular intervals on a line, so that the nanoparticle-containing fluid is uniformly sprayed from the nozzle 31. However, the nanoparticle supplying pipes 32 need not be arranged linearly, but can be arranged in any shape as long as the nanoparticle-containing fluid is sprayed uniformly from the nozzle 31. For example, the nanoparticle supplying pipes 32 can be arranged in a plurality of lines or the cross-sectional shape of the nanoparticle supplying pipe 32 can be a slit so that the nozzle 31 can be formed in a slit. In addition, although the cross-sectional shape of the nanoparticle supplying chamber 3 on the X-Y plane is rectangular elongated in the Y-axis direction in the above example, it can be made elliptical. Furthermore, because the nanoparticles are contained in a fluid, there is less possibility of clogging the pipes compared to the case of using powder nanoparticles, so that the nanoparticles can be supplied in a stable manner. Owing to the structure of the nanoparticle supplying chamber 3, the nanoparticles can be sprayed in a wide area on the substrate 5.

A controller 35 is connected to the nanoparticle supplying chamber 3, to spray the nanoparticle-containing fluid from the nozzle 31 as a mist 37. The controller 35 sprays the nanoparticle-containing fluid on the substrate 5 as the mist 37 from the container in which the nanoparticle-containing fluid is contained by driving a piezo element (not shown) that is installed near the nozzle 31.

In the first embodiment, a discharge method using parallel-plate electrodes is used to generate a plasma in the plasma treatment chambers 4a and 4b. The plasma treatment chambers 4a and 4b include gas supplying pipes 41a and 41b (hereinafter, also referred to as “gas supplying pipe 41” as appropriate) for supplying a gas for plasma treatment from a gas supplying unit 47, electrodes 43a and 43b (hereinafter, also referred to as “electrode 43” as appropriate) arranged near gas supplying ports 42a and 42b of the gas supplying pipes 41a and 41b, respectively, and connected to a plasma power source 45, ground electrodes 44a and 44b (hereinafter, also referred to as “ground electrode 44” as appropriate) as opposite electrodes to the electrodes 43a and 43b, respectively, and a cooling device (not shown). The electrodes 43a and 43b and the ground electrodes 44a and 44b will be collectively called as the plasma sources 46a and 46b (hereinafter, also referred to as the “plasma source 46” as appropriate), respectively. Although a discharge (radio-frequency (RF) discharge or direct-current (DC) glow discharge) using the parallel-plate electrodes is used as a method of generating the plasma in the first embodiment, other discharge schemes can be freely used, such as a microwave or an inductively-coupled plasma.

As shown in FIG. 2, the cross-sectional shapes of the plasma treatment chambers 4a and 4b on the X-Y plane are rectangular elongated in the Y-axis direction in the same manner as the nanoparticle supplying chamber 3. The plasma treatment chambers 4a and 4b include plural gas supplying pipes 41a and 41b arranged at virtually regular intervals on lines, respectively. With this structure, a uniform gas pressure and a uniform gas flow are generated between the electrode 43 and the ground electrode 44 so that a plasma treatment can be obtained in a wide area on the substrate 5. As shown in FIG. 4, for the discharge occurs in an atmospheric pressure or a state of low pressure (vacuum pressure), a distance between the electrode 43 and the ground electrode 44 is narrow.

A source gas supplied from the gas supplying unit 47 is flown between the electrodes 43a and 43b and the ground electrodes 44a and 44b through the gas supplying pipes 41a and 41b, respectively. A voltage for generating a plasma is applied from the plasma power source 45 to the electrodes 43a and 43b, and then plasmas 48a and 48b having elongated shapes are generated between the electrodes 43a and 43b and the ground electrodes 44a and 44b, respectively. With the plasmas 48a and 48b in the atmospheric pressure or the vacuum pressure, a large amount of heat is generated in an area that is irradiated with the plasmas 48a and 48b, such as the electrodes 43a and 43b and the ground electrodes 44a and 44b. Therefore, the plasma sources 46a and 46b are cooled by the cooling device that circulates a coolant such as water or fluorine-based inert fluid. The radiation amount of the plasma on the substrate 5 can be set according to the distance between the electrodes 43 and the ground electrodes 44, the gas pressure, and the gas flow rate; however, it is less than the radiation amount on the electrodes 43 and the ground electrodes 44.

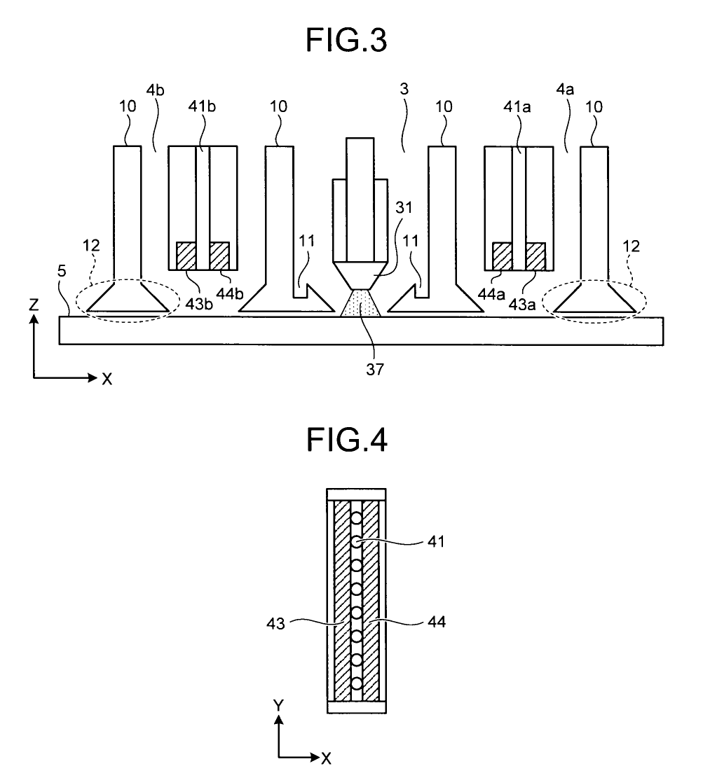

As shown in FIGS. 1 and 3, the nanoparticle supplying chamber 3 and the plasma treatment chambers 4a and 4b are surrounded by a bulkhead 10, and the exhausting unit 8a is connected to a space surrounded by the bulkhead 10 to exhaust the gas in the space. The bulkhead 10 that surrounds the nanoparticle supplying chamber 3 and the plasma treatment chambers 4a and 4b is arranged a few millimeters away from the substrate 5 not to make direct contact with the substrate 5.

The wall of the nanoparticle supplying chamber 3 and the bulkhead 10 are heated to a predetermined temperature by a heater or a warm fluid to prevent evaporated gases from being condensed. Furthermore, to prevent a drop of fluid onto the substrate 5 when a massive amount of the mist 37 is sprayed so that it is dispersed on the substrate 5 or when the evaporated gases are condensed in the nanoparticle supplying chamber 3, a groove 11 is provided at the inner side of the bulkhead 10 near the substrate 5 on the nanoparticle supplying chamber 3 side. A part of gases may penetrate into the plasma treatment chamber 4 through a space between the bulkhead 10 and the substrate 5 depending on a speed of moving the substrate 5; however, it is exhausted by a gas flow inside the plasma treatment chamber 4.

By setting a distance between the bottom of the plasma source 46 and the substrate 5 in the Z-axis direction larger than a distance between the substrate 5 and the bulkhead 10, because a conductance is smaller between the plasma source 46 and the bulkhead 10 is larger than between the bulkhead 10 and the substrate 5 due to the difference in distances therebetween, the source gas that does not contribute to the plasma at the time of plasma generation and the gas penetrated form the nanoparticle supplying chamber 3 are flown to the exhausting unit 8a through a space between the plasma source 46 and the bulkhead 10 and exhausted.

An end portion 12 of the bulkhead 10 that surrounds the plasma treatment chamber 4 is tapered in the inverse direction. In other words, the end portion 12 of the bulkhead 10 is formed in such a manner that the thickness of the bulkhead 10 is increased toward its bottom. Taking such an inverse-tapered structure, the source gas can be easily collected through the exhausting unit 8a. Although a part of the source gas can possibly be leaked out of the area when the substrate 5 is moved, as described above, the amount of gas leaked out of the area can be reduced with the help of the bulkhead 10 with the end portion 12 that is inverse-tapered. In addition, for the sake of safety, the source gas leaked from the space between the substrate 5 and the bulkhead 10 into other space in the main chamber 2 is exhausted by the exhausting unit 8b. Although the exhausting units 8a and 8b are formed as separate exhausting units in the above example, a common exhausting unit can be used for both the exhausting units 8a and 8b. Furthermore, although the end portion 12 of the bulkhead 10 is an inverse V shape in the above example, it can be formed in an inverse U shape having a curvature.

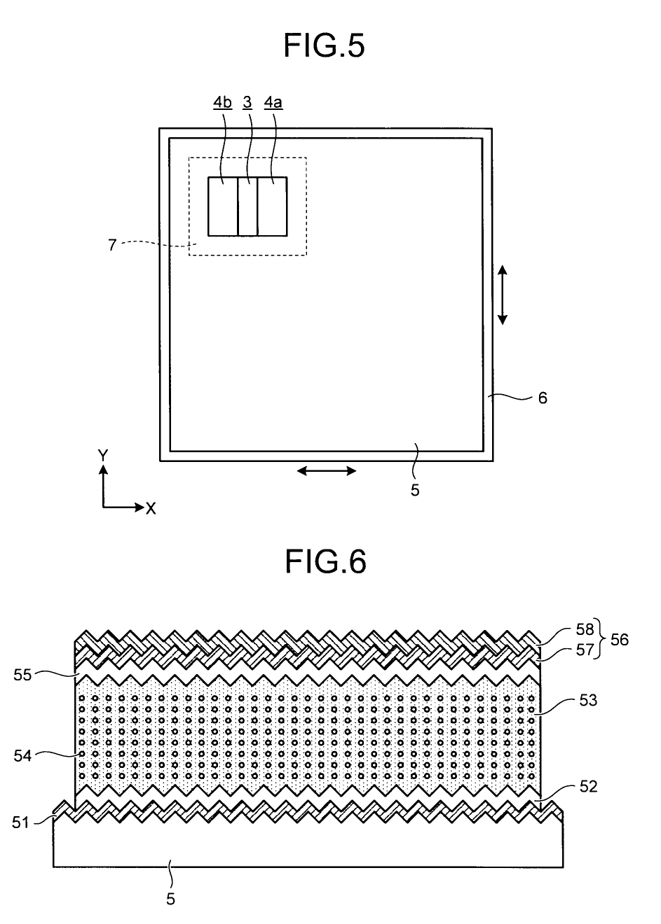

FIG. 5 is a schematic diagram for illustrating a positional relation between the nanoparticle supplying chamber 3 and the plasma treatment chambers 4a and 4b, the substrate 5, and the heater 7 viewed from above. As shown in FIG. 5, the heater 7 is located at an area surrounded by a broken line, and heats an area larger than a sum of an area of the substrate 5 where the mist 37 is sprayed from the nozzle 31 and an area of the substrate 5 irradiated with the plasmas 48a and 48b. As the heater 7, a noncontact heater that heats the substrate 5 in a noncontact manner, such as a lamp, or a contact heater that heats the substrate 5 by making contact with the substrate 5, such as a ceramic heater, can be used. The heater 7 can also heat the entire surface of the substrate 5. In the case of using the contact heater, the substrate holder 6 and the heater 7 are constructed to be moved integrally, such that, when the substrate holder 6 is moved, the heater 7 heats the area larger than the sum of the area of the substrate 5 where the mist 37 is sprayed from the nozzle 31 and the area of the substrate 5 irradiated with the plasmas 48a and 48b.

The substrate holder 6 holds the substrate 5, and moves the substrate 5 on the X-Y plane. During a deposition of a thinfilm, because the nanoparticle supplying chamber 3 and the plasma treatment chambers 4a and 4b are arranged side by side in the X-axis direction, a thinfilm containing the nanoparticles can be formed at a predetermined area on the substrate 5 by moving the substrate 5 in the X-axis direction while fixing a position in the Y-axis direction. When the substrate 5 is moved to the left (in the negative X-axis direction) in the state shown in FIG. 5, a silicon film is formed on the substrate 5 in the plasma treatment chamber 4a. After that, the mist 37 containing the nanoparticles is sprayed onto the silicon film in the nanoparticle supplying chamber 3 to form a nanoparticle layer, and subsequently, a silicon film is formed on the nanoparticle layer in the plasma treatment chamber 4b.

A method of forming a thinfilm using the thinfilm deposition apparatus 1 is explained below with a case of forming a photoelectric conversion layer of a thinfilm silicon-based solar cell as an example.

FIG. 6 is a cross section of a thinfilm silicon-based solar cell. As shown in FIG. 6, the thinfilm silicon-based solar cell includes a first electrode 51 made of transparent conductive material, a p-type silicon thinfilm 52, an i-type silicon thinfilm 53 in which silicon nanoparticles 54 are uniformly contained, an n-type silicon thinfilm 55, and a second electrode 56 consisting of a backside transparent conductive film 57 and a metal film 58 that reflects an incident light sequentially formed on a transparent substrate 5, such as a glass substrate, on which a texture structure is formed to efficiently use an incident sunlight.

When an alkali glass substrate is used as the substrate 5, a metal diffusion barrier film may be formed between the substrate 5 and the first electrode 51 to prevent a diffusion of an alkali metal such as sodium. Furthermore, an antireflection film may be formed between the substrate 5 and the first electrode 51 to efficiently use the incident sunlight. In FIG. 6, the metal diffusion barrier film and the antireflection film are omitted for ease of explanation.

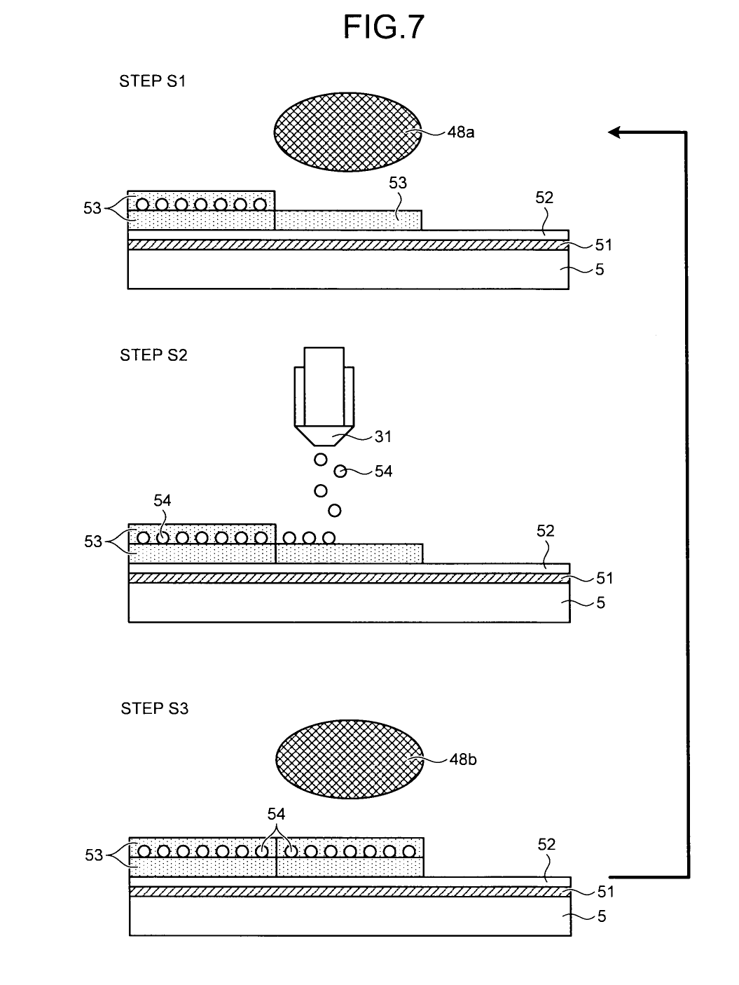

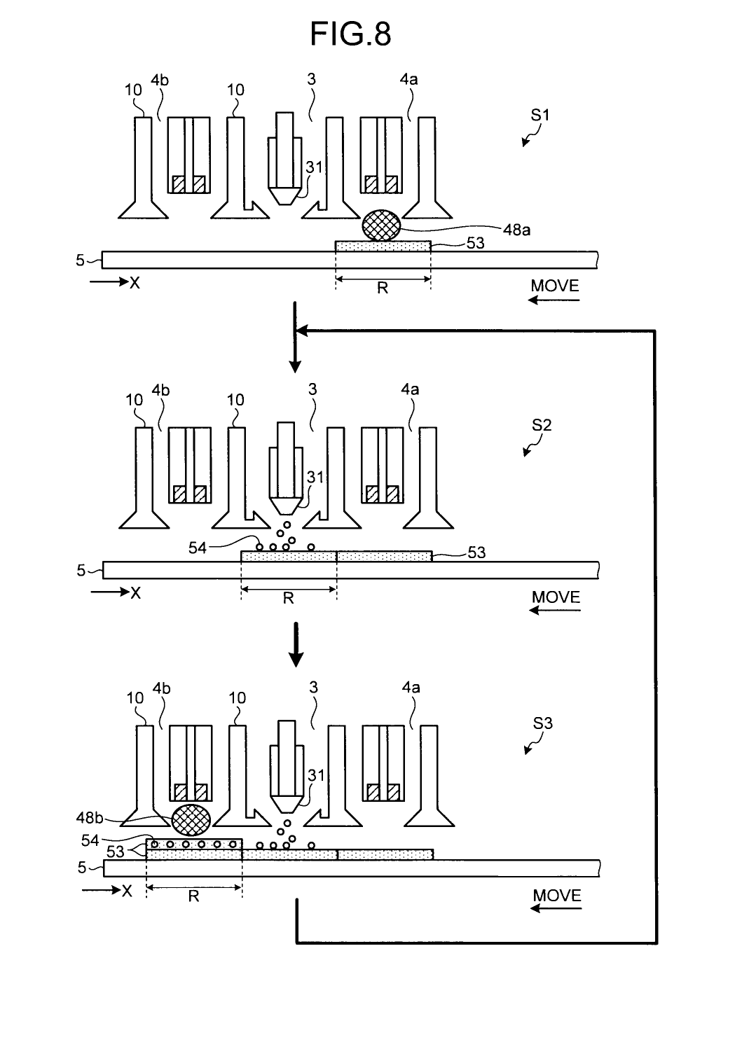

A case of forming the i-type silicon thinfilm 53 in the thinfilm silicon-based solar cell having the above structure by using the thinfilm deposition apparatus 1 is explained below as an example. FIG. 7 is a schematic diagram for explaining a process flow of a thinfilm deposition process; and FIG. 8 is a schematic diagram for explaining an overall procedure of the thinfilm deposition process shown in FIG. 7.

In the thinfilm deposition process shown in FIG. 7, a thinfilm is formed on a substrate using a plasma at Step S1, the nanoparticles are arranged on the thinfilm formed on the substrate at Step S2, and finally, a thinfilm is formed on the substrate with the nanoparticles arranged thereon at Step S3. With this process, a thinfilm containing the nanoparticles is formed. After Step S3, Steps S1 to S3 can be repeated to obtain a thinfilm having a desired thickness with the nanoparticles contained in a plurality of layers. Although Step S1 is a thinfilm deposition process in the process flow shown in FIG. 7, it can also be a plasma treatment process to activate the surface of the substrate. Alternatively, Step S1 can be set to switch between a plasma treatment to form a thinfilm and a plasma treatment to activate the surface of the substrate.

In the first embodiment, as shown in FIG. 8, the substrate on which the first electrode 51 and the p-type silicon film are formed is placed on the substrate holder 6, and after that, the pressure inside the main chamber 2 is set to the atmospheric pressure or a pressure slightly lower than the atmospheric pressure (vacuum pressure) by the gas supplying unit 47 and the exhausting units 8a and 8b. A state of a thinfilm deposition at an area R on the substrate 5 is explained below, where the substrate 5 is placed at the position shown in FIG. 5 and moved in the negative X-axis direction by the substrate holder 6. In the initial state, the area R is set opposite to the plasma treatment chamber 4a. The substrate 5 in this state is already heated to a predetermined temperature by the heater 7.

Silane (SiH₄) gas or mixed gas of silane and hydrogen (H₂) is supplied into the plasma treatment chamber 4a as the source gas to form a silicon thinfilm. The source gas is supplied from the gas supplying unit 47 that includes a gas container for a corresponding gas to the plasma treatment chamber 4a. The source gas is flown between the electrode 43a and the ground electrode 44a from the gas supplying pipe 41a. When a voltage is applied from the plasma power source 45 to the electrode 43a, the plasma 48a is generated between the electrode 43a and the ground electrode 44a. The radiation amount of the plasma on the substrate 5 can be set according to the distance between the electrode 43a and the ground electrode 44a, the gas pressure, and the gas flow rate.

A method of forming the i-type silicon thinfilm 53 that contains the nanoparticles 54 will be explained with reference to FIGS. 7 and 8. When the mixed gas of silane and hydrogen is used as the source gas, the plasma 48a includes dissociated ions of silane and hydrogen and electrons, precursors such as SiHx (x=1 to 3), and hydrogen atoms. Because, the pressure inside the main chamber 2 is relatively high (virtually near the atmospheric pressure), most of the charged particles such as the ions and the electrons are extinguished by a recombination while reaching the substrate 5; however, the neutral particles such as the precursors and the hydrogen atoms can reach the substrate 5 with the flow of the gas. The precursors and the hydrogen atoms terminate the silicon with the hydrogen to form a silicon thinfilm such as an amorphous silicon film on the area R of the substrate 5 (Step S1).

By moving the substrate 5 in the negative X-axis direction with the substrate holder 6, the silicon thinfilm can be formed with a width depending on the distance between the electrode 43a and the ground electrode 44a (the width of the plasma source 46a) in the direction (Y-axis direction) perpendicular to the direction of moving the substrate 5. During the generation of the plasma, the walls of the plasma treatment chambers 4a and 4b and the bulkhead 10 are heated to a predetermined temperature by a heater or a warm fluid to prevent the silicon film from being deposited on the wall.

With the movement of the substrate 5 in the negative X-axis direction by the substrate holder 6, the area R on which the silicon thinfilm is formed is moved to a position opposite to the nanoparticle supplying chamber 3. In the nanoparticle supplying chamber 3, the nanoparticle-containing fluid is supplied from the nanoparticle supplying unit 34, and it is sprayed on the area R of the substrate 5 from the nozzle 31 as the mist 37. The cross section of the nanoparticle supplying chamber 3 on the X-Y plane is an elongated rectangular shape as shown in FIG. 2, and the nanoparticle-containing fluid is sprayed in a predetermined width from the nozzles 31 or a slit-like elongated nozzle as the mist 37. Because the average size of droplets that can be sprayed is about 2 micrometers at minimum, the average particle size of the nanoparticles 54 is equal to or smaller than 1 micrometer to uniformly contain the nanoparticles 54 in the droplets. Meanwhile, the average particle size of the nanoparticles 54 should preferably be equal to or larger than 1 nanometer (or a few nanometers). By setting the average particle size of the nanoparticles 54 to a few nanometers to 1 micrometer, it is possible to make a solar cell with optical characteristics for a light having a wavelength of a few nanometers to 1 micrometer. The number of nanoparticles 54 arranged on the substrate 5 can be adjusted by the concentration of the nanoparticles 54 in the fluid and the size and the overlapping of the droplets sprayed in the nanoparticle supplying chamber 3. The fluid component in the droplets reaching the substrate 5 is evaporated because the substrate 5 is heated by the heater 7, so that the nanoparticles 54 contained in the droplets are arranged on the substrate 5 in a virtually uniform manner (Step S2). The evaporated vapor of the fluid is exhausted outside the main chamber 2 by the exhausting unit 8a through a space around the nozzle 31 shown in FIGS. 2 and 3.

After depositing the nanoparticles 54 on the substrate 5, the substrate 5 is further moved by the substrate holder 6 in the negative X-axis direction until the area R on which the nanoparticles 54 are arranged is placed opposite to the plasma treatment chamber 4b. In the plasma treatment chamber 4b a silicon thinfilm is formed on the area R on which the nanoparticles 54 are arranged in the same manner as the case in the plasma treatment chamber 4a (Step S3).

By repeatedly moving the substrate 5 back and forth in the X-axis direction, while fixing the position in the Y-axis direction, the i-type silicon thinfilm 53 that contains the nanoparticles 54 can be formed in a plurality of layers in the thickness (Z-axis) direction. In this manner, the i-type silicon thinfilm 53 that contains the nanoparticles 54 therein can be formed by repeating Steps 1 to 3 shown in FIG. 7, by depositing a silicon thinfilm on the nanoparticles 54 that is arranged on a silicon thinfilm and repeating the whole procedure until a desired thickness is obtained. Furthermore, by performing the above thinfilm deposition process including the nanoparticles for each position in the Y-axis direction as shown in FIG. 5, the i-type silicon thinfilm 53 that contains the nanoparticles 54 on a large size substrate 5.

With the configuration of the thinfilm deposition apparatus 1 described above, because the plasma treatment chamber 4a is arranged on one side and the plasma treatment chamber 4b is arranged on the other side of the nanoparticle supplying chamber 3 in the X-axis direction, the thinfilm deposition process can be performed by moving the substrate 5 in both directions (positive and negative directions) of the X-axis. Alternatively, a single plasma treatment chamber can be provided on one side of the nanoparticle supplying chamber and the thinfilm deposition process can be performed by moving the substrate 5 in only one direction (either positive or negative direction) of the X-axis.

In this way, a thinfilm silicon-based solar cell including the i-type silicon thinfilm 53 that contains the silicon nanoparticles 54 can be fabricated using the thinfilm deposition apparatus 1 shown in FIG. 1. Because the i-type silicon thinfilm 53 contains the silicon nanoparticles 54, it is possible to increase the spectral sensitivity in a long-wavelength range compared to a case without the nanoparticles 54. In other words, the wavelength range of the sunlight can be efficiently used, and as a result, the efficiency of the solar cell can be increased.

The p-type silicon thinfilm 52 and the n-type silicon thinfilm 55 of the thinfilm silicon-based solar cell shown in FIG. 6 can be formed using either the thinfilm deposition apparatus 1 or other thinfilm deposition apparatus. In the case of using the thinfilm deposition apparatus 1, the p-type silicon thinfilm 52 can be formed by adding diborane (B₂H₆) to the mixed gas of silane and hydrogen, and the n-type silicon thinfilm 55 can be formed by adding phosphine (PH₃) to the mixed gas of silane and hydrogen. However, in this case, the nozzle 31 in the nanoparticle supplying chamber 3 is set to a nonoperational state by the controller 35.

Although a fluid is used as a medium for supplying the nanoparticles 54 in the nanoparticle supplying chamber 3 in the above example, a gas can be used as the medium alternatively. Furthermore, although a silicon thinfilm is used as an example in the above description, the thinfilm to be deposited and the nanoparticles are not limited to the silicon, but can be any other materials such as dielectric, metal, and semiconductor.

According to the first embodiment, a thinfilm in which nanoparticles are arranged with a desired concentration can be formed at a desired area, and a thinfilm (solar cell) having desired characteristics can be fabricated in a stable manner, by arranging the nanoparticle supplying chamber 3 in which a fluid containing the nanoparticles 54 is sprayed in a direction of moving the substrate 5 and the plasma treatment chambers 4a and 4b for depositing a thinfilm side by side and alternately repeating thinfilm depositions in the plasma treatment chambers 4a and 4b and an arrangement of nanoparticles in the nanoparticle supplying chamber 3.

Furthermore, according to the first embodiment, because the thinfilm is deposited at the atmospheric pressure or a pressure close to the atmospheric pressure, the structure of the apparatus can be simplified with easy maintenance, and the thinfilm can be formed at high speed. In addition, because a high vacuum is not necessary in the main chamber 2, an energy-saving effect can be obtained at the same time. Moreover, because the nanoparticle supplying chamber 3 for performing a process of arranging the nanoparticles and the plasma treatment chambers 4a and 4b for depositing the thinfilm are separated from each other, even when the plasmas 48a and 48b are extinguished, there is no such trouble that the nanoparticles fall on the thinfilm unlike the conventional case.

Moreover, according to the first embodiment, because there is no heating by a thermal spray, there is no worry about an alteration of a base coating or the substrate 5 unlike the conventional case. In addition, by using the above thinfilm deposition apparatus, it is possible to fabricate a thinfilm semiconductor device that includes a thinfilm in which nanoparticles are uniformly arranged. By setting the average particle size of the nanoparticles to equal to or smaller than 1 micrometer, it is possible to make a thinfilm silicon-based solar cell with optical characteristics for a wavelength range equal to or shorter than 1 micrometer.

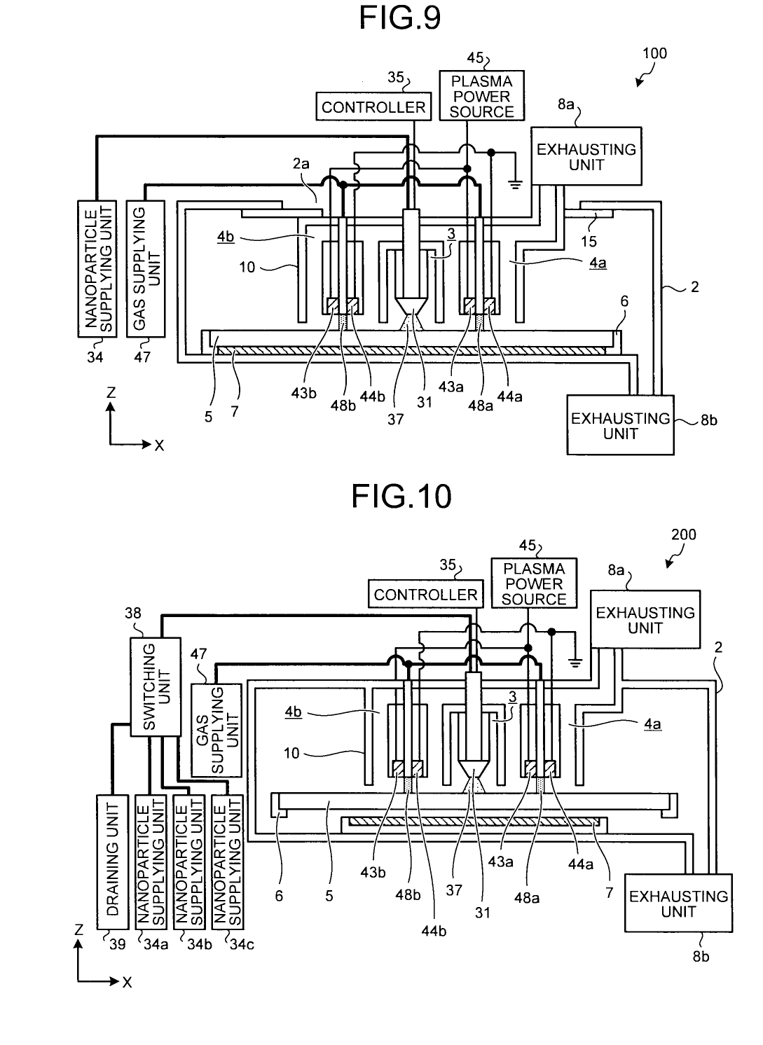

FIG. 9 is a schematic diagram of a thinfilm deposition apparatus 100 according to a second embodiment of the present invention. The thinfilm deposition apparatus 100 has a configuration that the substrate holder 6 is fixed to the main chamber 2, and the nanoparticle supplying chamber 3 and the plasma treatment chambers 4a and 4b are made to move relative to the main chamber 2 in the thinfilm deposition apparatus 1 according to the first embodiment.

The main chamber 2 includes an opening 2a, a supporting member 15 that covers the opening 2a provided being in tight contact with the top of the main chamber 2, and a moving unit (not shown) that moves the supporting member 15 on the X-Y plane (plane of the substrate). Upper parts of the nanoparticle supplying chamber 3, the plasma treatment chambers 4a and 4b, and the bulkhead 10 are fixed to the supporting member 15. The substrate holder 6 and the heater 7 are integrally arranged so that the heater 7 can heat the substrate 5 when the substrate 5 is placed on the substrate holder 6. In the example shown in FIG. 9, the heater 7 forms the bottom of the substrate holder 6. With this structure, the heater 7 can heat the whole area of the substrate 5, so that a temperature control of the substrate 5 can be easily performed compared to the thinfilm deposition apparatus 1 according to the first embodiment. For the same constituent elements as those explained in the first embodiment, the same reference numerals are assigned and explanations therefore are omitted.

The same effects as the first embodiment can be obtained in the second embodiment.

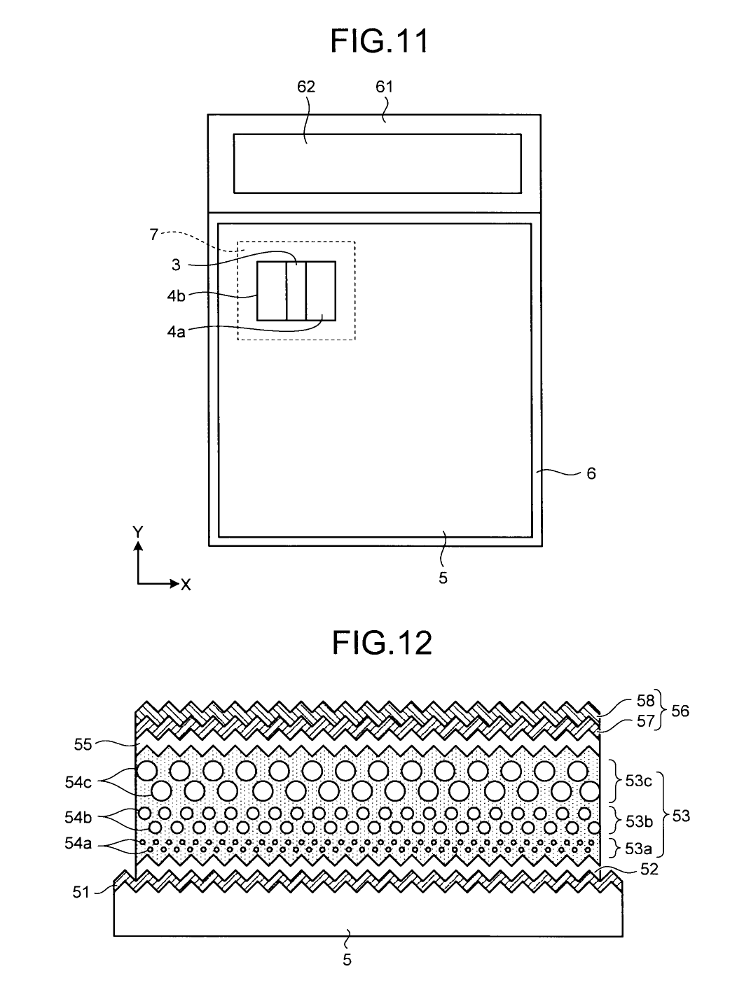

FIG. 10 is a schematic diagram of a thinfilm deposition apparatus 200 according to a third embodiment of the present invention. The thinfilm deposition apparatus 200 includes a plurality of nanoparticle supplying units 34a, 34b, and 34c, a switching unit 38, and a draining unit 39 in the thinfilm deposition apparatus 1 according to the first embodiment. Furthermore, as shown in FIG. 11, the substrate holder 6 includes a dummy-substrate holder 61 for holding a dummy substrate 62 in addition to the substrate 5. For the same constituent elements as those explained in the above embodiments, the same reference numerals are assigned and explanations therefore are omitted.

In the nanoparticle supplying units 34a, 34b, and 34c, nanoparticle-containing fluids having different average particle sizes are contained, respectively, and the particle size distribution of the nanoparticles are adjusted in advance. The average particle sizes of the nanoparticles contained in the nanoparticle supplying units 34a, 34b, and 34c are represented by ra, rb, and rc (ra<rb<rc), respectively. Although the three units of the nanoparticle supplying units 34a, 34b, and 34c are shown in FIG. 10, the number of nanoparticle supplying units is not limited to any particular number.

The switching unit 38 is arranged between the nanoparticle supplying chamber 3 and the nanoparticle supplying units 34a, 34b, and 34c, and switches between the nanoparticle supplying units 34a, 34b, and 34c to supply a nanoparticle-containing fluid containing nanoparticles having a desired particle size when arranging the nanoparticles on the substrate 5.

The draining unit 39 drains a residual nanoparticle-containing fluid remained in a nanoparticle supplying pipe connecting the switching unit 38 and the nanoparticle supplying chamber 3 when the switching unit 38 switches the nanoparticle supplying unit between the nanoparticle supplying units 34a, 34b, and 34c.

As shown in FIG. 11, the dummy-substrate holder 61 is arranged adjacent to an area where the substrate 5 is placed, and holds the dummy substrate 62. Because the draining unit 39 cannot completely drain the residual nanoparticle-containing fluid near the nozzle 31, some residual nanoparticle-containing fluid is remained there. Therefore, after the switching unit 38 switches to a desired nanoparticle supplying unit from the nanoparticle supplying units 34a, 34b, and 34c and the draining unit drains the residual nanoparticle-containing fluid, the substrate holder 6 is moved such that the dummy substrate 62 is placed opposite to the nozzle 31, and the residual nanoparticle-containing fluid is sprayed on the dummy substrate 62. The dummy substrate 62 is taken out of the main chamber 2 at the time of regular maintenance to remove the nanoparticles on the dummy substrate 62.

With this structure, it is possible to select the average particle size of the nanoparticles to be arranged on the substrate by using the switching unit 38. Furthermore, when switching the desired nanoparticle supplying unit, residual nanoparticle-containing fluid that is used before switching the nanoparticle-containing fluid and remained in the nanoparticle supplying pipe connected to the nanoparticle supplying chamber 3 and the nozzle 31 can be completely drained. Moreover, inside the main chamber 2 is at the atmospheric pressure or a vacuum pressure, a maintenance operation can be performed easily.

The method of depositing a thinfilm containing the nanoparticles using the thinfilm deposition apparatus 200 is basically same as the procedures explained in the first embodiment. However, because the thinfilm deposition apparatus 200 further performs an operation of switching the nanoparticle supplying unit, overall procedures of performing a thinfilm deposition with the operation of switching the nanoparticle supplying unit will be explained below.

After depositing a silicon thinfilm on the substrate 5 in the plasma treatment chamber 4a, nanoparticles having the average particle size of ra is arranged on the silicon thinfilm by using a nanoparticle-containing fluid from the nanoparticle supplying unit 34a, and a silicon thinfilm is deposited on the substrate 5 in the plasma treatment chamber 4b. After forming a layer containing the nanoparticles having the average particle size of ra to a desired thickness, the switching unit 38 switches from the nanoparticle supplying unit 34a to the nanoparticle supplying unit 34b, and then the nanoparticle-containing fluid containing the nanoparticles having the average size of ra remained in the nanoparticle supplying pipe 32 and the nozzle 31 is drained. A process of forming a silicon thinfilm while arranging nanoparticles having the average particle size of rb is performed until the silicon thinfilm containing the nanoparticles having the average particle size of rb with a desired thickness is obtained using a nanoparticle-containing fluid from the nanoparticle supplying unit 34b, the switching unit 38 switches from the nanoparticle supplying unit 34b to the nanoparticle supplying unit 34c, and then the nanoparticle-containing fluid containing the nanoparticles having the average size of rb remained in the nanoparticle supplying pipe 32 and the nozzle 31 is drained. After that, a process of forming a silicon thinfilm while arranging nanoparticles having the average particle size of rc is performed until the silicon thinfilm containing the nanoparticles having the average particle size of rc with a desired thickness is obtained using a nanoparticle-containing fluid from the nanoparticle supplying unit 34c. In this manner, a silicon thinfilm containing the nanoparticles can be formed by sequentially switching the nanoparticle-containing fluid from the nanoparticle-containing fluids having different average particle sizes.

FIG. 12 is a cross section of one of thinfilm silicon-based solar cells fabricated by the thinfilm deposition apparatus 200 shown in FIG. 10. Using the above method, a thinfilm silicon-based solar cell shown in FIG. 12 can be fabricated. The thinfilm silicon-based solar cell shown in FIG. 12 has a configuration in which the i-type silicon thinfilm 53 shown in FIG. 6 is configured with a layer 53a containing nanoparticles 54a having the average particle size of ra, a layer 53b containing nanoparticles 54b having the average particle size of rb, a layer 53c containing nanoparticles 54c having the average particle size of rc, in order from the substrate 5 side.

In the i-type silicon thinfilm 53 in which the nanoparticles 54a to 54c having different average particle sizes are arranged, the bandgap of the silicon thinfilm increases as the average particle size of the nanoparticles increases. In other words, the spectral sensitivity in a long-wavelength range of the sunlight increases as the average particle size of the nanoparticles increases. Therefore, by increasing the average particle size of the silicon particles contained in the i-type silicon thinfilm 53 sequentially from the incidence plane side of the sunlight, it is possible to obtain a solar cell having a photoelectric conversion layer that can utilize a broad wavelength range of the sunlight, i.e., a solar cell with a high efficiency.

In addition to the effects obtained in the first embodiment, another effect is obtained in the third embodiment that a thinfilm containing nanoparticles having different average particle sizes can be formed. Furthermore, because a nanoparticle-containing fluid containing nanoparticles of a different average particle size is sprayed on the substrate 5 after complete removing the residual nanoparticle-containing fluid remained in a nanoparticle supplying pipe connecting a corresponding nanoparticle supplying unit and the nanoparticle supplying chamber 3 and the nozzle 31 when switching the nanoparticle-containing fluid to the nanoparticle-containing fluid containing nanoparticles of a different average particle size, the thickness of a thinfilm layer containing the nanoparticles having each average particle size can be precisely controlled.

Moreover, by increasing the average particle size of the nanoparticles 54a to 54c contained in the film sequentially from the incidence plane side of the sunlight in the i-type silicon thinfilm 53 of the thinfilm silicon-based solar cell, it is possible to form a photoelectric conversion layer that can utilize a broad wavelength range of the sunlight, so that a solar cell with a high efficiency can be obtained. Furthermore, the average particle sizes of the nanoparticles 54a to 54c having different average particle sizes can be changed according to the thickness of a film. In addition, by using the thinfilm deposition apparatus 1, it is possible to fabricate a thinfilm device that includes a thinfilm in which the average particle size of nanoparticles contained in the thinfilm is changed in the thickness direction of the thinfilm. In particular, by arranging nanoparticles having different average particle sizes in a silicon thinfilm, it is possible to broaden the wavelength range in the sunlight that can be used in a solar cell, to increase the conversion efficiency, and to efficiently use the energy.

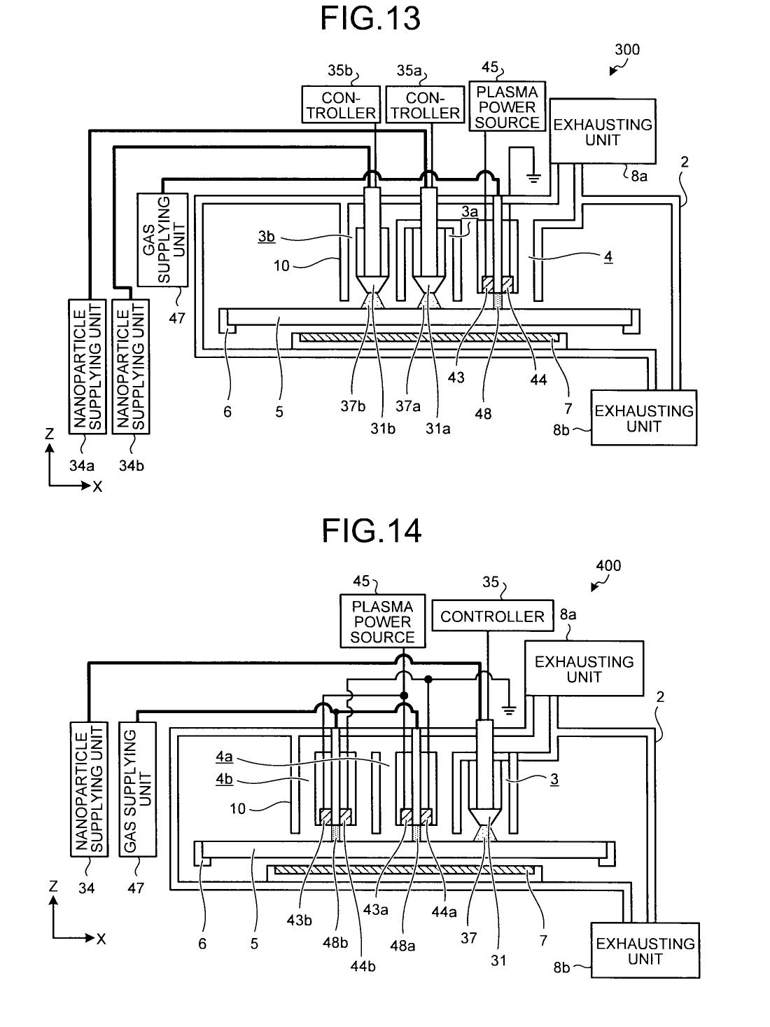

FIG. 13 is a schematic diagram of a thinfilm deposition apparatus 300 according to a fourth embodiment of the present invention. The thinfilm deposition apparatus 300 includes a plurality of nanoparticle supplying chambers 3a and 3b, a plurality of nanoparticle supplying units 34a and 34b, a plurality of controllers 35a and 35b, and a plasma treatment chamber 1 in the thinfilm deposition apparatus 1 according to the first embodiment. Although two units of the nanoparticle supplying chambers 3a and 3b, the nanoparticle supplying units 34a and 34b, and the controllers 35a and 35b are provided, respectively, in the example shown in FIG. 13, the number of units is not limited to any particular number. For the same constituent elements as those explained in the above embodiments, the same reference numerals are assigned and explanations therefore are omitted.

Nanoparticle-containing fluids having different average particle sizes are contained in the nanoparticle supplying units 34a and 34b, respectively, and nozzles 31a and 31b of the nanoparticle supplying chambers 3a and 3b connected to the nanoparticle supplying units 34a and 34b are controlled to be an operational state or a nonoperational state by the controllers 35a and 35b, respectively, so that the average particle size of the nanoparticles to be arranged on the substrate 5 can be changed.

Because the method of depositing a thinfilm containing the nanoparticles using the thinfilm deposition apparatus 300 is basically same as the procedures explained in the above embodiments, an explanation therefore will be omitted. By using the thinfilm deposition apparatus 300, it is possible to fabricate the thinfilm silicon-based solar cell shown in FIG. 12.

In addition, by continuously arranging nanoparticles from the nanoparticle supplying unit 34b in the nanoparticle supplying chamber 3b right after arranging nanoparticles from the nanoparticle supplying unit 34a in the nanoparticle supplying chamber 3a, it is also possible to form a thinfilm including nanoparticles having a plurality of average particle sizes.

In addition to the effects obtained in the third embodiment, another effect is obtained in the fourth embodiment that a thinfilm including nanoparticles having a plurality of average particle sizes in a single thinfilm layer can be formed.

Although the nanoparticle supplying chambers 3a and 3b are provided for the nanoparticle supplying units 34a and 34b, respectively, it is possible to obtain the same effects by providing the nozzles 31a and 31b that is respectively connected to the nanoparticle supplying units 34a and 34b in a single nanoparticle supplying chamber.

Although the nanoparticles of the same material are used in the fourth embodiment, nanoparticles of different materials can be used in the fluids of the nanoparticle supplying units 34a and 34b, respectively, so that a thinfilm can be formed by changing the material of the nanoparticles to be contained in the thinfilm.

In an alternative configuration, the number of plasma treatment chambers and the nanoparticle supplying chambers arranged in the direction of moving the substrate can be more than one. FIG. 14 is a schematic diagram of a thinfilm deposition apparatus 400 according to a fifth embodiment of the present invention. The thinfilm deposition apparatus 400 includes a single unit of the nanoparticle supplying chamber 3, and two units of the plasma treatment chambers 4a and 4b sequentially arranged in the X-axis direction. The plasma source 46a generates a hydrogen plasma 48a, and the plasma source 46b generates a plasma 48b for depositing a silicon thinfilm. With this configuration, impurities that are contained in the fluid, not completely evaporated, and attached to surfaces of the silicon nanoparticles arranged on the substrate 5 in the nanoparticle supplying chamber 3 are removed by the hydrogen plasma 48a in the plasma treatment chamber 4a. Then, a silicon film can be formed by terminating the surfaces of the silicon nanoparticles and the surface of the substrate 5 with hydrogen with a plasma treatment in the plasma treatment chamber 4b, so that the film quality of a finally-formed silicon thinfilm containing the nanoparticles can be improved. Furthermore, because a time between the plasma treatments includes only a time for moving the substrate 5, the treatment process can be performed continuously, and as a result, there is less degradation of the film quality with time.

Although the hydrogen plasma treatment is performed in the plasma treatment chamber 4a and the silicon thinfilm is formed in the plasma treatment chamber 4b in the fifth embodiment, other plasma treatments can be performed in the plasma treatment chambers. Furthermore, the plasma treatment chambers 4a and 4b and the nanoparticle supplying chamber 3 are not limited to the above examples.

According to the fifth embodiment, because a plurality of plasma treatment chambers are arranged next to the nanoparticle supplying chamber 3, the impurities that are contained in the fluid, not completely evaporated, and attached to surfaces of the silicon nanoparticles arranged on the substrate 5 in the nanoparticle supplying chamber 3 are removed by the hydrogen plasma in the plasma treatment chamber 4a, and then a silicon film can be formed by the plasma in the plasma treatment chamber 4b.

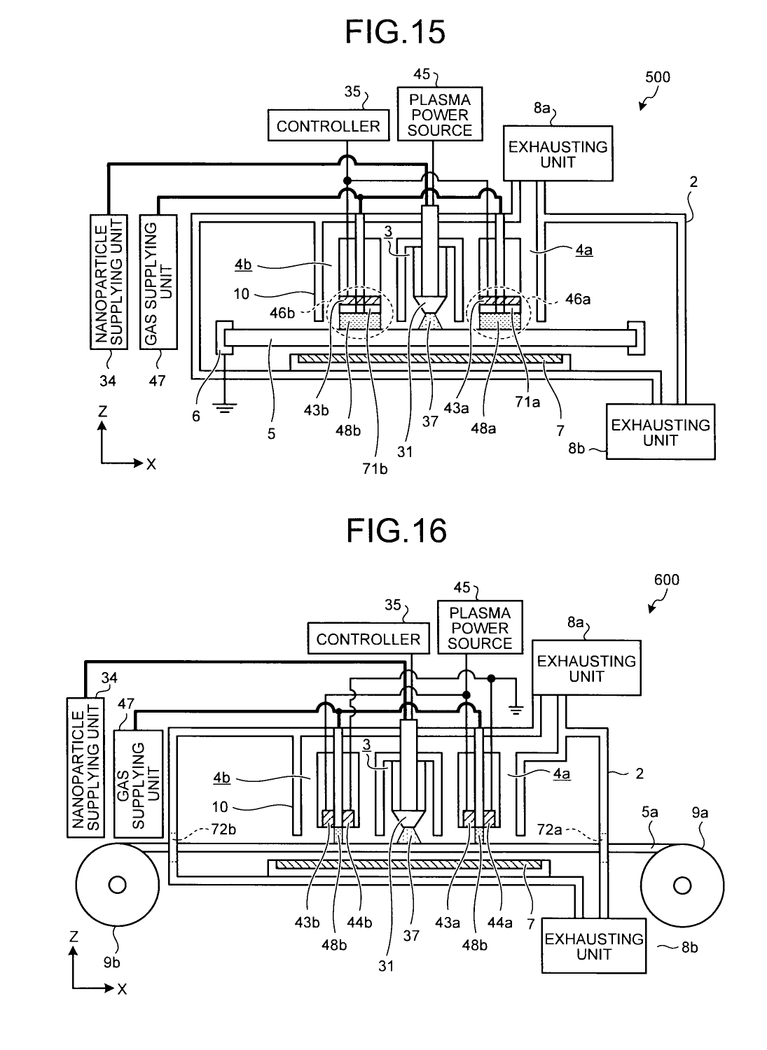

In a sixth embodiment of the present invention, a case of configuring a plasma source using a method other than the above-described plasma generating methods will be explained. FIG. 15 is a schematic diagram of a thinfilm deposition apparatus 500 according to the sixth embodiment. The thinfilm deposition apparatus 500 has a configuration that the electrodes 43a and 43b of the plasma sources 46a and 46b are covered by dielectrics 71a and 71b, respectively, and the substrate 5 functions as the ground electrodes 44a and 44b in the thinfilm deposition apparatus 1 according to the first embodiment. For the same constituent elements as those explained in the first embodiment, the same reference numerals are assigned and explanations therefore are omitted.

The plasma sources 46a and 46b having the above structure is effective when the substrate 5 is conductive or when a conductive film is formed on the surface of the substrate 5. In this case, the plasma treatment can be performed by connecting the surface of the substrate 5 to the ground via the substrate holder 6 and generating the plasma 48a and 48b between the substrate 5 and the electrodes 43a and 43b. Because the substrate 5 (the substrate holder 6) is grounded, the influx of the charged particles in the plasma 48a and 48b onto the substrate 5 is increased. On the other hand, in the plasma sources 46a and 46b described in the first embodiment, because the electrodes 43a and 43b and the ground electrodes 44a and 44b are arranged opposite to each other with the surface of the electrodes perpendicular to the surface of the substrate, respectively, small amounts of charged particles reach the substrate 5 from the plasma 48a and 48b. Conclusively, the amount of charged particles incident on the substrate 5 can be increased by using the plasma sources 46a and 46b according to the sixth embodiment.

In the sixth embodiment, because the amount of charged particles incident on the substrate 5 can be increased in the plasma sources 46a and 46b in the plasma treatment chambers 4a and 4b, a deposition speed can be increased in a thinfilm deposition that employs a reaction in which an acceleration effect by an ion is high in a film deposition mechanism.

FIG. 16 is a schematic diagram of a thinfilm deposition apparatus 600 according to a seventh embodiment of the present invention. The thinfilm deposition apparatus 600 has a configuration that can be applied to a thinfilm deposition on a film-type substrate 5a in the thinfilm deposition apparatus 1 according to the first embodiment. The thinfilm deposition apparatus 600 includes rollers 9a and 9b for feeding and returning the film-type substrate 5a on both sides of the main chamber 2 in the X-axis direction, and openings 72a and 72b for passing the film-type substrate 5a through the main chamber 2 at positions corresponding to the rollers 9a and 9b. In this case, the movement of the film-type substrate 5a in the X-axis direction is performed by rotating the rollers 9a and 9b, and the movement of the film-type substrate 5a in the Y-axis direction is performed by a moving unit (not shown) that synchronously moves the rollers 9a and 9b in the Y-axis direction.

In the seventh embodiment, because the rollers 9a and 9b on which the film-type substrate 5a is wound is provided outside the main chamber 2 and the film-type substrate 5a is moved by winding it with a rotation of the rollers 9a and 9b, the size of the apparatus can be decreased in the X-axis direction compared to the first embodiment.

So far, a method of spraying a nanoparticle-containing fluid is explained as an example of a method of arranging nanoparticles on a substrate; however, a method of spraying a gas that contains the nanoparticles (hereinafter, “a nanoparticle-containing gas”) can be alternatively employed.

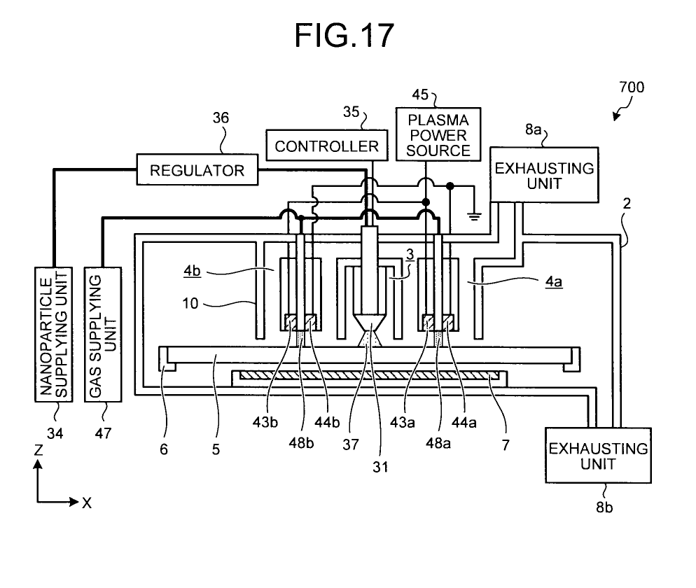

FIG. 17 is a schematic diagram of a thinfilm deposition apparatus 700 according to an eighth embodiment of the present invention. A difference between the thinfilm deposition apparatus 1 and the thinfilm deposition apparatus 700 is that a nanoparticle-containing gas is supplied from the nanoparticle supplying unit 34 to the nanoparticle supplying chamber 3. The thinfilm deposition apparatus 700 includes the nanoparticle supplying unit 34 that has a function of supplying the nanoparticles using a gas as a medium and a regulator 36 between the nanoparticle supplying unit 34 and the nozzle 31. The nanoparticle-containing gas is supplied from the nanoparticle supplying unit 34 to the nanoparticle supplying chamber 3 via the regulator 36 and sprayed from the nozzle 31 onto the substrate 5. The nozzle 31 is controlled on and off by the controller 35. The regulator 36 is provided to prevent an accidental massive spray of the nanoparticle-containing gas due to a sudden change of the pressure in a gas pipe. By keeping the gas flow and the gas pressure constant with the regulator 36, the gas flow from the nozzle 31 can be kept stable. For the same constituent elements as those explained in the first embodiment, the same reference numerals are assigned and explanations therefore are omitted.

The cross-sectional shape of the bulkhead 10 that surrounds the nanoparticle supplying chamber 3 and the plasma treatment chambers 4a and 4b is the same as the one shown in FIG. 3. The groove 11 is provided at the bottom portion of the bulkhead 10 to prevent nanoparticles that cannot be collected by the exhausting unit 8a from falling on the substrate 5 because the nanoparticle-containing gas can possibly be filled in the nanoparticle supplying chamber 3 depending on a condition due to the spray of the nanoparticle-containing gas.

Because the method of depositing a thinfilm containing the nanoparticles using the thinfilm deposition apparatus 700 is basically same as the procedures explained in the above embodiments, an explanation therefore will be omitted. Although a case of applying the method of spraying a nanoparticle-containing gas on the substrate 5 to the first embodiment is explained as an example, the method of using the nanoparticle-containing gas can be applied to the other embodiments explained above.

In the eighth embodiment, it is possible to form a thinfilm in which nanoparticles are uniformly contained similar to the first embodiment.

According to one aspect of the present invention, because a nanoparticle-containing medium that contains nanoparticles is sprayed on a surface of a substrate, the nanoparticles can be arranged at desired areas, and at the same time, a thinfilm deposition apparatus can be obtained which forms a thinfilm in which the nanoparticles are evenly arranged. Furthermore, because a nanoparticle supplying chamber from which the nanoparticles are sprayed is separated from a plasma treatment chamber for depositing the thinfilm, the nanoparticles are kept from penetrating into the plasma treatment chamber. Therefore, even if the plasma is extinguished, the nanoparticles are not deposited on the thinfilm, unlike the conventional case. Moreover, because the thinfilm is not formed by the spray method, it is possible to prevent an alteration of a base coating or a substrate due to a thermal energy.

Although the invention has been described with respect to a specific embodiment for a complete and clear disclosure, the appended claims are not to be thus limited but are to be construed as embodying all modifications and alternative constructions that may occur to one skilled in the art that fairly fall within the basic teaching herein set forth.

What is claimed is:

1. A thinfilm deposition method comprising:
plasma treatment processing including either one of depositing a thinfilm on a surface of a substrate by dissociating a source gas in a plasma and treating the surface of the substrate with the source gas in the plasma;
nanoparticle arranging including arranging nanoparticles on the surface of the substrate, which has been subjected to the plasma treatment processing, by spraying a nanoparticle-containing fluid onto the surface of the substrate, wherein
a treatment process of performing the plasma treatment processing and the nanoparticle arranging in a same chamber is defined as one cycle, and
the thinfilm deposition method further comprises repeating the one cycle of the treatment process.

2. The thinfilm deposition method according to claim 1, wherein the nanoparticle arranging is included a plurality of times in the one cycle.

3. The thinfilm deposition method according to claim 1, wherein the plasma treatment processing is included a plurality of times in the one cycle.

4. A thinfilm deposition apparatus comprising:
a substrate holding unit that holds a substrate while heating a part or whole of the substrate;
a plasma treatment chamber that is connected to a source-gas supplying unit that supplies a source gas, the plasma treatment chamber including a gas passage for introducing the source gas to a vicinity of the substrate and a plasma generating unit that generates a plasma from the source gas supplied from the gas supplying pipe;
a nanoparticle supplying chamber that is connected to a nanoparticle-containing-medium supplying unit that supplies a nanoparticle-containing medium that contains nanoparticles, the nanoparticle supplying chamber including a spraying member for spraying the nanoparticle-containing medium supplied from the nanoparticle-containing-medium supplying unit onto a surface of the substrate;
a collecting unit that collects the source gas from the plasma treatment chamber and the nanoparticle-containing medium from the nanoparticle supplying chamber; and
a main chamber that commonly accommodates the substrate holding unit, the plasma treatment chamber, and the nanoparticle supplying chamber.

5. The thinfilm deposition apparatus according to claim 4, wherein
the plasma treatment chamber and the nanoparticle supplying chamber are arranged adjacent to each other, and
surfaces of the plasma treatment chamber and the nanoparticle supplying chamber in a direction perpendicular to a plane opposing the substrate are surrounded by bulkheads, respectively.

6. The thinfilm deposition apparatus according to claim 5, wherein an end portion of the bulkhead has an inverse-tapered shape such that a thickness of the end portion gradually increases toward the substrate.

7. The thinfilm deposition apparatus according to claim 5, wherein the bulkhead on the nanoparticle supplying chamber side includes a groove formed at an inner side near the substrate.

8. The thinfilm deposition apparatus according to claim 4, wherein
the spraying member includes either one of a perforated member having a plurality of perforations arranged on a line and a slit member having a slit extending in one direction, and
the plasma treatment chamber includes either one of a plurality of gas passages arranged on a line and a slit port on a side opposing the substrate.

9. The thinfilm deposition apparatus according to claim 4, further comprising a moving unit that moves the substrate holding unit or the plasma treatment chamber and the nanoparticle supplying chamber in a direction parallel to the surface of the substrate.

10. The thinfilm deposition apparatus according to claim 4, wherein the nanoparticle-containing-medium supplying unit includes a plurality of nanoparticle-containing-medium supplying units, and
the thinfilm deposition apparatus further comprises a switching unit that is provided between the nanoparticle-containing-medium supplying units and the spraying member and that switches between the nanoparticle-containing-medium supplying units to switch the nanoparticle-containing medium to be supplied to the nozzle.

11. The thinfilm deposition apparatus according to claim 10, further comprising a draining unit that drains a residual nanoparticle-containing medium between the nanoparticle supplying chamber and the switching unit before the switching unit switches between the nanoparticle-containing-medium supplying units.

12. The thinfilm deposition apparatus according to claim 11, wherein
the substrate holding unit includes a dummy-substrate holding unit that holds a dummy substrate, and
after the switching unit switches between the nanoparticle-containing-medium supplying units and the draining unit drains the residual nanoparticle-containing medium, the spraying member sprays a residual nanoparticle-containing medium remained near the nozzle on the dummy substrate.

13. The thinfilm deposition apparatus according to claim 4, wherein
the nanoparticle supplying chamber includes a plurality of nanoparticle supplying chambers, and
the nanoparticle-containing-medium supplying unit includes a plurality of nanoparticle-containing-medium supplying units respectively corresponding to the nanoparticle supplying chambers.

14. The thinfilm deposition apparatus according to claim 4, wherein either the plasma treatment chamber includes a plurality of plasma treatment chambers or the nanoparticle supplying chamber includes a plurality of nanoparticle supplying chambers.

15. The thinfilm deposition apparatus according to claim 4, wherein
the substrate is a film-like substrate, and
the substrate holding unit is configured with a pair of rollers on which the film-like substrate is wound.

16. The thinfilm deposition apparatus according to claim 4, wherein the nanoparticle-containing medium is in fluid form.

17. The thinfilm deposition apparatus according to claim 4, wherein the nanoparticle-containing medium is in gaseous form.

18. A thinfilm semiconductor device comprising:
a transparent substrate;
a first electrode formed on the substrate, the first electrode being made of transparent conductive material;
a first semiconductor film formed on the first electrode, the first semiconductor film being made of first conductive semiconductor;
a second semiconductor film formed on the first semiconductor film, the second semiconductor film being made of intrinsic semiconductor;
a third semiconductor film formed on the second semiconductor film, the third semiconductor film being made of second conductive semiconductor; and
a second electrode formed on the third semiconductor film, wherein
the second semiconductor film includes a plurality of uniformly-arranged nanoparticles having a predetermined average particle size.

19. The thinfilm semiconductor device according to claim 18, wherein the average particle size of the nanoparticles gradually increases from the substrate side toward the second electrode.
